(19) United States
(12) Patent Application Publication
(10) Pub. No.: US 2011/0159696 A1
(43) Pub. Date: Jun. 30, 2011

(54) METHOD OF MANUFACTURING SEMICONDUCTOR DEVICES

(76) Inventor: MYUNG KYU AHN, GYEONGGI-DO (KR)

(21) Appl. No.: 12/973,382

(22) Filed: Dec. 20, 2010

(30) Foreign Application Priority Data
Dec. 30, 2009 (KR) 10-2009-0134120

(51) Int. Cl. H01L 21/302

(52) U.S. Cl. 438/703; 257/E21.214

(57) ABSTRACT

A method of manufacturing semiconductor devices comprises forming an etch target layer and auxiliary patterns over a semiconductor substrate, forming spacers on sidewalls of the auxiliary patterns, removing the auxiliary patterns, performing an etch process to change both corners of upper portions of the spacers to be symmetrical to one another, and patterning the etch target layer by using the spacers.

### CROSS-REFERENCE TO RELATED APPLICATION

Priority to Korean patent application number 10-2009-0134120 filed on Dec. 30, 2009, the entire disclosure of which is incorporated by reference herein, is claimed.

### BACKGROUND

Exemplary embodiments relate to a method of manufacturing semiconductor devices and, more particularly, to a method of manufacturing semiconductor devices which is capable of preventing a pattern tilting phenomenon.

A semiconductor device includes a plurality of gate patterns and metal lines. With the trend toward the high degree of integration of semiconductor devices, the width and pitch of patterns, including the gate patterns and the metal lines, are decreasing.

In order to facilitate forming of a pattern with a narrow width while increasing the degree of integration of semiconductor devices as described above, a patterning process using spacer technology has been introduced.

This is described in detail with reference to the drawings.

FIGS. 1A to 1C are cross-sectional views showing a method of manufacturing semiconductor devices, with which concerns in a conventional manufacturing method are illustrated.

Referring to FIG. 1A, an etch target layer 12 is formed over a semiconductor substrate 10. The etch target layer 12 may be formed of an insulating layer, a conductive layer (or a metal layer), or a stack layer thereof. For example, in a case where final patterns to be formed are the gate patterns of a flash memory device, the etch target layer 12 may be formed by stacking a tunnel insulating layer, a first conductive layer for floating gates, a dielectric layer, and a second conductive layer for control gates. In another case where the final pattern are metal lines, the etch target layer 12 may be formed of a metal layer.

Auxiliary patterns 14 having a wider pitch than the final patterns are formed over the etch target layer 12. In order to form the auxiliary patterns 14, an auxiliary layer, a bottom anti-reflective coating (BARC) layer, and a photoresist pattern (not shown) are sequentially formed and an etch process is then performed along the photoresist pattern, thereby forming an anti-reflective pattern 16 and the auxiliary patterns 14.

Next, a spacer layer 18 is formed along the surfaces of the auxiliary patterns 14, the anti-reflective pattern 16, and the exposed etch target layer 12.

Referring to FIG. 1B, an etch process is performed to expose the anti-reflective pattern (16 of FIG. 1A). Here, some of the spacer layer 18 between the auxiliary patterns (14 of FIG. 1A) are also removed, thereby exposing some of the etch target layer 12. Consequently, spacers 18a, which are formed by the spacer layer (18 of FIG. 1A) remaining on the sidewalls of the auxiliary patterns (14 of FIG. 1A), are formed. The anti-reflective pattern 16 and the auxiliary patterns 14 exposed between the spacers 18a are sequentially removed so that only the spacers 18a remain over the etch target layer 12.

Here, the upper portions of the spacers 18a may have asymmetrical forms, as described by 20a and 20b, due to the characteristics of a manufacturing process.

Referring to FIG. 1C, a patterning process using the spacers 18a as a hard mask is performed on the etch target layer (12 of FIG. 1B), thereby forming etch target patterns 12a. The patterning process may be performed using a dry etch process.

In particular, when the patterning process is performed, the asymmetrical forms of the spacers 18a may be transferred to the etch target layer, for example, without change. Accordingly, the forms of the etch target patterns 12a may also have asymmetrical forms (22a and 22b).

If the sidewalls of the etch target patterns 12a are formed with different tilts from each other as described above, a bridge may occur between the lower sides thereof, and the etch target patterns 12a may have different electrical properties. Consequently, the electrical properties of a flash memory device may be deteriorated, resulting in low reliability thereof.

### BRIEF SUMMARY

An exemplary embodiment relates to a semiconductor device including patterns of a regular form.

A method of manufacturing semiconductor devices according to an exemplary aspect of the present disclosure comprises forming an etch target layer and auxiliary patterns over a semiconductor substrate, forming spacers on the sidewalls of the auxiliary patterns, removing the auxiliary patterns, performing an etch process to change both corners of upper portions of the spacers to be symmetrical to one another, and patterning the etch target layer by using the spacers.

Forming the auxiliary patterns may comprise forming a first auxiliary layer, a second auxiliary layer, and photoresist patterns over the etch target layer, patterning the second auxiliary layer and the first auxiliary layer along the photoresist patterns to form the auxiliary patterns, and removing the photoresist patterns.

The first auxiliary layer may be formed of an amorphous carbon layer, and the second auxiliary layer may be formed of a silicon oxynitride (SiON) layer, a bottom anti-reflective coating (BARC) layer, or a stack of the SiON layer and the BARC layer.

The photoresist patterns may be formed to have a pitch twice greater than a pitch of the patterned etch target layer.

The etch process may be performed by using a dry etch process. The etch process may be performed by using a plasma sputtering etch process.

The plasma sputtering etch process may be performed by supplying an inert gas to a chamber. Here, argon (Ar), helium (He), neon (Ne), and xenon (Xe) either alone or in combination may be used as the inert gas.

The plasma sputtering etch process may be performed by supplying bias power of 200 W to 1000 W and maintaining pressure within a chamber to range from 10 mTorr to 50 mTorr.

The etch process may be performed by using capacitively coupled plasma (CCP) type equipment, inductively coupled plasma (ICP) type equipment, or microwave plasma type equipment alone, or by using equipment combining processes of at least two of foregoing equipments.

The etch process may be performed in the same chamber in-situ or different chambers ex-situ with respect a chamber for removing the auxiliary patterns.

The etch target layer may be performed by using a dry etch process.

### BRIEF DESCRIPTION OF THE DRAWINGS

FIGS. 1A to 1C are cross-sectional views showing a method of manufacturing semiconductor devices; and

FIGS. 2A to 2G are cross-sectional views illustrating a method of manufacturing semiconductor devices according to an exemplary embodiment of this disclosure.

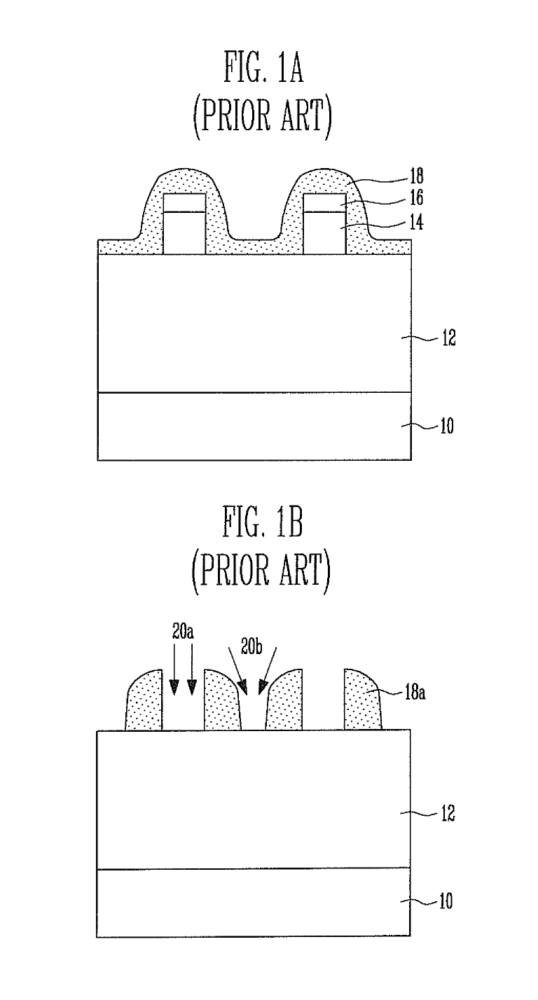

### DESCRIPTION OF EMBODIMENT

Hereinafter, an exemplary embodiment of the present disclosure will be described in detail with reference to the accompanying drawings. The figures are provided to enable those of ordinary skill in the art to make and use the exemplary embodiments of the disclosure.

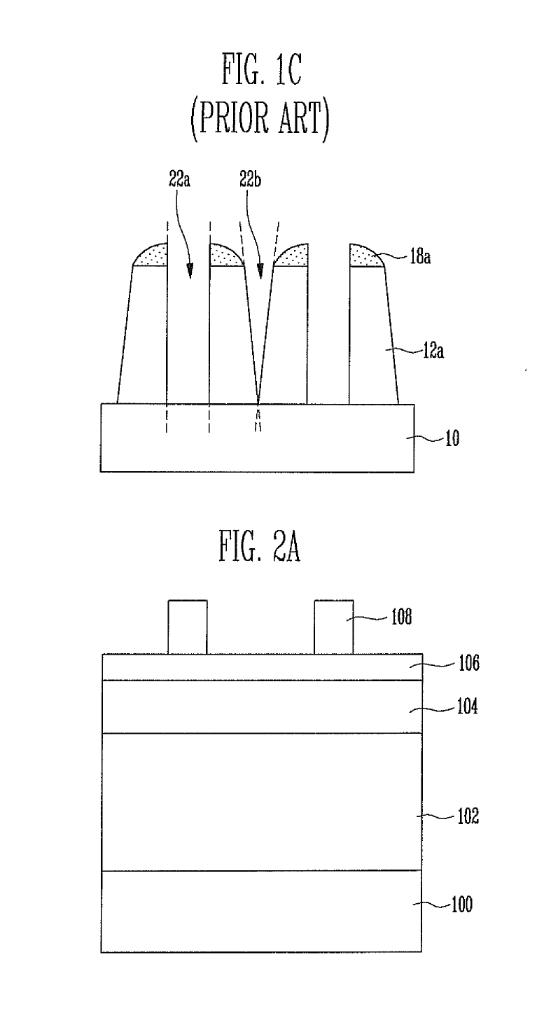

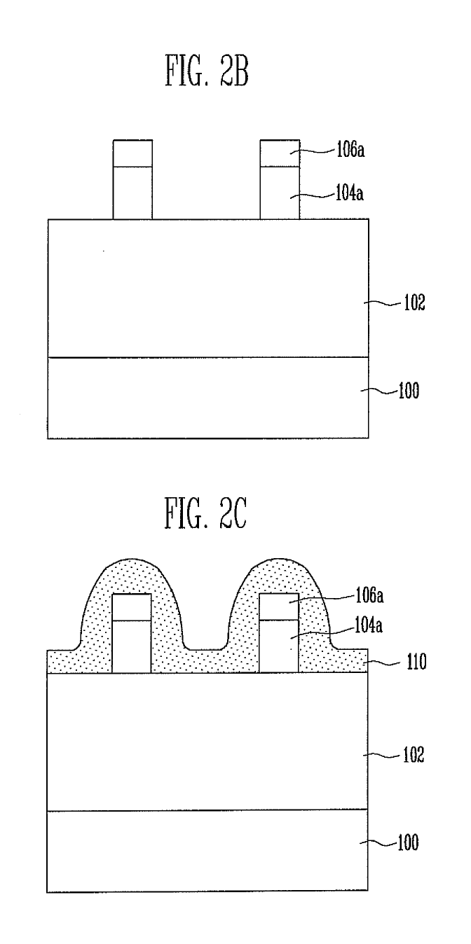

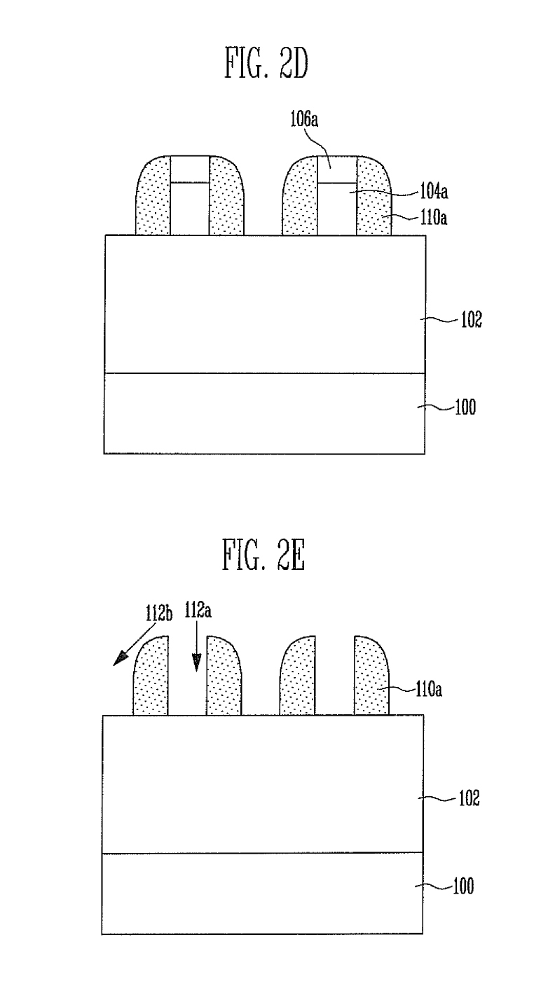

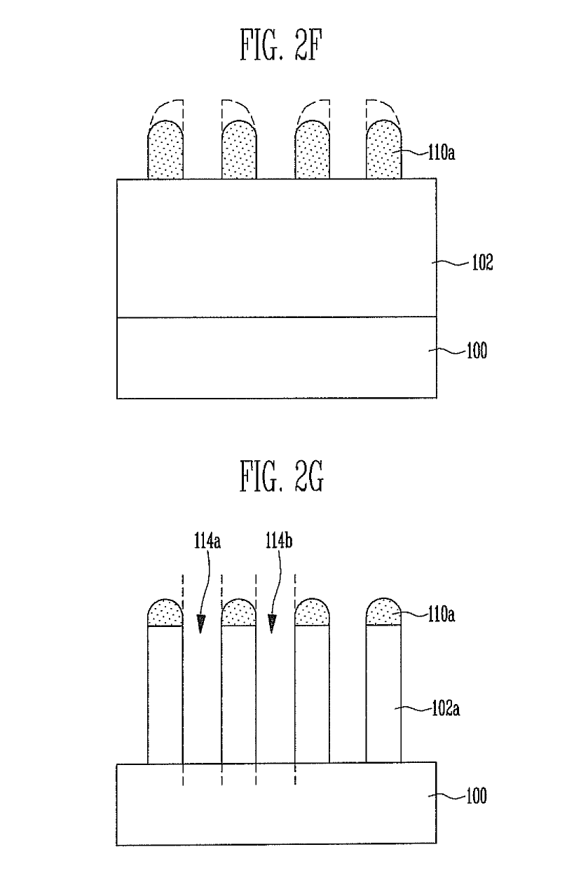

FIGS. 2A to 2G are cross-sectional views illustrating a method of manufacturing semiconductor devices according to an exemplary embodiment of this disclosure.

Referring to FIG. 2A, an etch target layer 102, a first auxiliary layer 104, a second auxiliary layer 106, and photoresist patterns 108 are sequentially formed over a semiconductor substrate 100. The etch target layer 102 may be formed of an insulating layer, a conductive layer, or a stack of the insulating layer and the conductive layer. For example, in case where the etch target layer 102 is for forming the gates of a flash memory device, the etch target layer 102 may be formed by stacking a tunnel insulating layer, a first conductive layer for floating gates, a dielectric layer, and a second conductive layer for control gates. The first auxiliary layer 104 may be formed of an amorphous carbon layer, and the second auxiliary layer 106 may be formed of a silicon oxynitride (SiON) layer, a bottom anti-reflective coating (BARC) layer, or a stack of the BARC layer and the SiON layer. The photoresist patterns 108 are formed to have a wider pitch than patterns to be finally formed and preferably formed to have a pitch twice greater than that of the final patterns.

Referring to FIG. 2B, second auxiliary patterns 106a and first auxiliary patterns 104a are formed by performing a first patterning process using the photoresist patterns (108 of FIG. 2A) as a mask. The photoresist patterns (108 of FIG. 2A) may be fully removed during the first patterning process for forming the first and second auxiliary patterns 104a and 106a, but preferably be removed by performing a removal process if they remain.

Referring to FIG. 2C, a spacer layer 110 is formed on an exposed surface of the first and second auxiliary patterns 104a and 106a and the etch target layer 102. It is preferred that the spacer layer 110 have a thickness identical with the width of the first and second auxiliary patterns 104a and 106a. In particular, the thickness of the spacer layer 110 formed on the sidewalls of the first and second auxiliary patterns 104a and 106a is identical with the width of the first and second auxiliary patterns 104a and 106a.

Referring to FIG. 2D, the spacer layer (110 of FIG. 2C) is etched through a first etch process so that the second auxiliary patterns 106a and a part of the etch target layer 102 are exposed. Here, the etch target layer 102 in an area between the first and second auxiliary patterns 104a and 106a is exposed. The first etch process may preferably be performed using a blanket etch process. Accordingly, spacers 110a are formed by the spacer layer remaining on the sidewalls of the first and second auxiliary patterns 104a and 106a.

Referring to FIG. 2E, the second auxiliary patterns 106a and the first auxiliary patterns 104a exposed between the spacers 110a are sequentially removed so that only the spacers 110a remain over the etch target layer 102. Here, the upper portions of the spacers 110a have an asymmetrical form in view of the process of forming the spacers 110a, and the sidewalls of the spacers 110a also have an irregular tilt. That is, the sidewalls 112a of the spacers 110a in which the first and second auxiliary patterns 104a and 106a have been formed are almost vertical to the etch target layer 102, but the sidewalls 112b of the spacers 110a on the other side have a tilted form. The spacers 110a are used as a mask in a subsequent patterning process, and so the tilted form (i.e., asymmetrical form) may have an effect on the final patterns of the etch target layer 102.

Referring to FIG. 2F, a second etch process is performed in order to change the asymmetrical forms on the upper portions of the spacers 110a to be symmetrical. That is, the second etch process preferably is performed using a dry etch process. Here, according to the characteristic of the dry etch process, angled portions or corners are more etched than other areas. Accordingly, both corners on the upper portions of the spacers 110a can become symmetrical because the pointed portion of the spacers 110a are more quickly etched than other portions. The second etch process preferably is performed using a plasma sputtering etch process and may be performed in the same chamber in-situ or different chambers ex-situ after the process of removing the first and second auxiliary patterns (refer to FIG. 2E). The plasma sputtering etch process is performed by supplying an inert gas to the chamber. Argon (Ar), helium (He), neon (Ne), and xenon (Xe) either alone or in combination may be used as the inert gas. In order to improve the plasma sputtering etch characteristic, it is preferred that high bias power of 200 W to 1000 W be supplied and pressure within the chamber be maintained to range from 10 mTorr to 50 mTorr. Furthermore, in the second etch process, capacitively coupled plasma (CCP) type equipment, inductively coupled plasma (ICP) type equipment, microwave plasma type equipment or equipment combining different processes of the foregoing equipments may be used as etch equipment.

Referring to FIG. 2G, the etch target layer (102 of FIG. 2F) is patterned by performing a second patterning process using the spacers 110a as a mask pattern, thereby forming etch target patterns 102a.

In particular, in the second etch process, the upper portions of the spacers 110a used as the mask patterns were formed to have the symmetrical form. Accordingly, the direction in which the second pattern process is performed (i.e., the direction in which the etch gas travels) may become almost vertical to the etch target layer 102, and so both sidewalls of the etch target patterns 102a can be formed to have the same tilt. Consequently, the generation of bridges can be suppressed, and the second patterning process can be performed so that portions 114a and 114b between the etch target patterns 102a have the same width.

As described above, since the upper portions of the mask patterns (i.e., spacers) used in the second patterning process are formed to have a symmetrical form, patterns to be formed can have a uniform form. Accordingly, a deterioration of the electrical properties of a semiconductor device can be prevented/reduced, and its reliability can be improved. Furthermore, the patterns of semiconductor devices can be formed to have a regular form and to be almost vertical to the semiconductor substrate. Although the degree of integration of semiconductor devices is increased, the patterns can be formed so that a deterioration of electrical properties of the semiconductor devices can be prevented/reduced. Accordingly, appropriate reliability of the semiconductor devices can be obtained.

What is claimed is:

1. A method of manufacturing semiconductor devices, comprising:
forming an etch target layer and auxiliary patterns over a semiconductor substrate;
forming spacers on sidewalls of the auxiliary patterns;
removing the auxiliary patterns;
performing an etch process to change both corners of upper portions of the spacers to be symmetrical to one another; and
patterning the etch target layer by using the spacers.

2. The method of claim 1, wherein the forming of the auxiliary patterns comprises:
forming a first auxiliary layer, a second auxiliary layer, and photoresist patterns over the etch target layer;
patterning the second auxiliary layer and the first auxiliary layer along the photoresist patterns to form the auxiliary patterns; and
removing the photoresist patterns.

3. The method of claim 2, wherein:
the first auxiliary layer is formed of an amorphous carbon layer, and
the second auxiliary layer is formed of a silicon oxynitride (SiON) layer, a bottom anti-reflective coating (BARC) layer, or a stack of the SiON layer and the BARC layer.

4. The method of claim 2, wherein the photoresist patterns are formed to have a pitch twice greater than a pitch of the patterned etch target layer.

5. The method of claim 1, wherein the etch process is performed by using a dry etch process.

6. The method of claim 1, wherein the etch process is performed by using a plasma sputtering etch process.

7. The method of claim 6, wherein the plasma sputtering etch process is performed by supplying an inert gas to a chamber.

8. The method of claim 7, wherein argon (Ar), helium (He), neon (Ne), and xenon (Xe) either alone or in combination are used as the inert gas.

9. The method of claim 6, wherein the plasma sputtering etch process is performed by supplying bias power of 200 W to 1000 W and maintaining pressure within a chamber to range from 10 mTorr to 50 mTorr.

10. The method of claim 1, wherein the etch process is performed by using capacitively coupled plasma (CCP) type equipment, inductively coupled plasma (ICP) type equipment, or microwave plasma type equipment alone, or by using equipment that combines processes of at least two of the CCP type equipment, the ICP type equipment, and the microwave plasma type equipment.

11. The method of claim 1, wherein the etch process is performed in an identical chamber in-situ or different chambers ex-situ with respect to a chamber for removing the auxiliary patterns.

12. The method of claim 1, wherein patterning the etch target layer is performed by a dry etch process.

13. The method of claim 1, wherein the forming of the spacers comprises:
forming a spacer layer over an entire surface of the semiconductor substrate having the etch target layer and the auxiliary patterns; and
etching the spacer layer to expose the auxiliary patterns and the etch target layer between the auxiliary patterns.

14. The method of claim 13, wherein the spacer layer is formed to have a thickness equal to the width of the auxiliary patterns.
